(19) United States
(12) Patent Application Publication
(10) Pub. No.: US 2025/0309149 A1
(43) Pub. Date: Oct. 2, 2025

(54) MICROELECTRONIC STRUCTURES INCLUDING EMBEDDED ETCH STOP IN PACKAGE CORE

(71) Applicant: Intel Corporation, Santa Clara, CA (US)

(72) Inventors: Jeremy Ecton, Gilbert, AZ (US); Brandon C. Marin, Gilbert, AZ (US); Srinivas Pietambaram, Chandler, AZ (US); Gang Duan, Chandler, AZ (US)

(73) Assignee: Intel Corporation, Santa Clara, CA (US)

(21) Appl. No.: 18/621,817

(22) Filed: Mar. 29, 2024

(51) Int. Cl. H01L 23/64; H01L 21/48; H01L 23/00; H01L 23/538

(52) U.S. Cl. CPC H01L 23/642; H01L 21/486; H01L 23/5383; H01L 23/5384; H01L 24/13; H01L 24/16; H01L 2224/13111; H01L 2224/13139; H01L 2224/13144; H01L 2224/13147; H01L 2224/16225

(57) ABSTRACT

Microelectronic integrated circuit package structures include an apparatus having a first core layer, an interface layer on the first core layer, and a second core layer the interface layer. A device structure is on the interface layer and embedded within the first core layer, the device structure comprising one or more trench capacitors extending partially through a thickness of the device structure. One or more conductive via structures are adjacent to the device structure, wherein the one or more conductive via structures extend through the interface layer.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

Some package architectures may include embedded passive devices, such as deep trench capacitors (DTC) s which may be embedded into a package substrate core. In some cases, a DTC may be fabricated using silicon technology, where a thickness of the DTC is limited to a thickness of a silicon wafer as well as by silicon processing limitations. This thickness limitation can become an issue for a core with a thickness that is greater than 600 microns. Such an embedded silicon based DTC is prone to shifting or rotation within the cavity of the core during and after encapsulation within the core. For example, a thin DTC which is limited to about a 600 micron thickness, when embedded into a core with a thickness that is greater than 600 microns will result in a thickness mismatch between the DTC and the substrate core. This thickness mismatch can lead to significant yield, reliability, and manufacturability challenges. In addition, voiding may occur a result of insufficient filling of encapsulant material as well as vertical and tilt misalignment during embedding.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1D are cross-sectional views of IC package structures comprising an embedded IC device, in accordance with some embodiments.

FIGS. 2A-2E are cross-sectional views of IC forming package structures comprising an embedded IC device, in accordance with some embodiments.

FIGS. 3A-3L are cross-sectional views of IC package structures comprising placing an embedded IC device in a core, in accordance with some embodiments.

FIG. 4 is a cross-sectional view of an IC package structures comprising an embedded IC device, in accordance with some embodiments.

FIG. 5 illustrates a flow chart of processes for the fabrication of IC package structures having an embedded IC device, in accordance with some embodiments.

FIG. 6 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of′ or “one or more of′ can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods of embedding passive devices, such as deep trench capacitors (DTCs) into a package substrate. Embedding capacitors into a substrate core, for example enables the achievement of a fully integrated voltage regulator (FIVR). The embodiments herein include fabricating device structures, such as DTCs and embedding one or more DTCs within one or more core layers of a package substrate. In an embodiment, a first core and a second core stack comprise an interface layer, such as an etch stop layer, between the first and second cores. The first and second cores are bonded to each other by the interface layer. A DTC is embedded in the first core, where a top surface of the DTC is substantially coplanar with a top surface of the first core. A bottom surface of the DTC is on a top surface of the interface layer in an embodiment.

In other embodiments, the bottom surface of the DTC may be partially within a portion of a thickness of the interface layer, or the bottom surface may be on a top surface of the second core. A primary benefit of the present disclosure includes the ability to precisely position a DTC within a core of a package structure to prevent shifting or rotation of the DTC within the core. DTC thicknesses can be easily tailored to different products and a desired embedding core layer by tailoring a thickness of the interface layer during packaging fabrication operations.

Embodiments describe methods of fabricating a multi core package substrate having one or more device structures embedded within one or more core layers of the package substrate. In an embodiment, a first core layer and a second core layer may comprise an interface layer between them. The interface layer may act as an etch stop layer on the second core layer, such that the etch stop layer facilitates the placement of a device structure within the first core layer. In an embodiment, the device structure is on or at least partially within the interface layer, the device structure comprising one or more trench capacitors. A metal/insulator/metal film stack is formed within individual trenches to form a DTC. A second portion of the device structure is below the first portion, wherein the second portion is free of the one or more trenches.

One or more conductive via structures are adjacent to the device structure, wherein the one or more conductive via structures extend through a portion of the interface layer as well as through the first and second core layers. An electrical routing structure comprising a redistribution layer (RDL) metallization in some embodiments may be built-up on at least one side of the core portion, and integrated circuit (IC) die(s) may be assembled to interconnect with the routing structure. The embodiments herein enable a cost-efficient process that can prevent shifting or rotation of passive devices (such as DTCs) within a multi core package substrate, as well as enabling optimization of a thickness of a core layer and a thickness of a DTC.

The architecture described herein may be assembled and/or fabricated with one or more of the features or attributes provided in accordance with various embodiments. A number of different assembly and/or fabrication methods may be practiced to enable passive structures such as DTC's to be reliably embedded within a package structure, according to one or more of the features or attributes described herein.

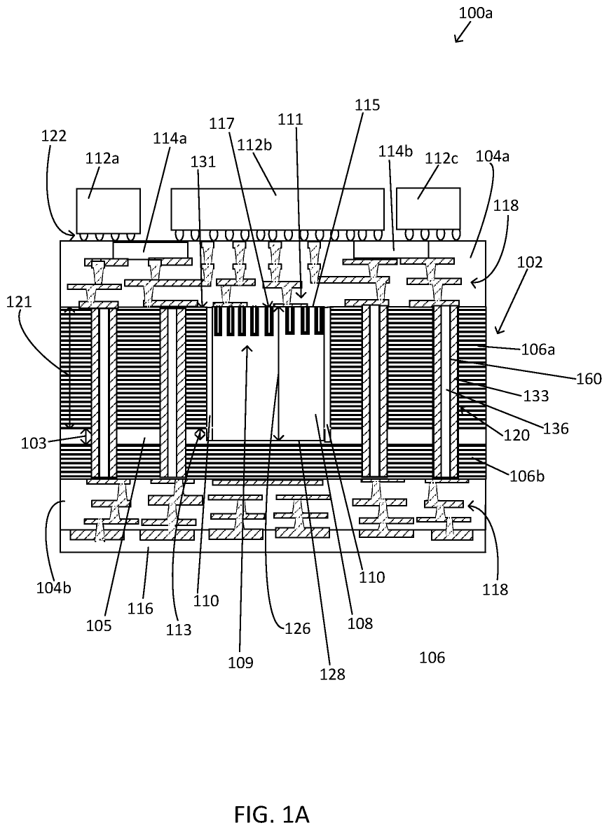

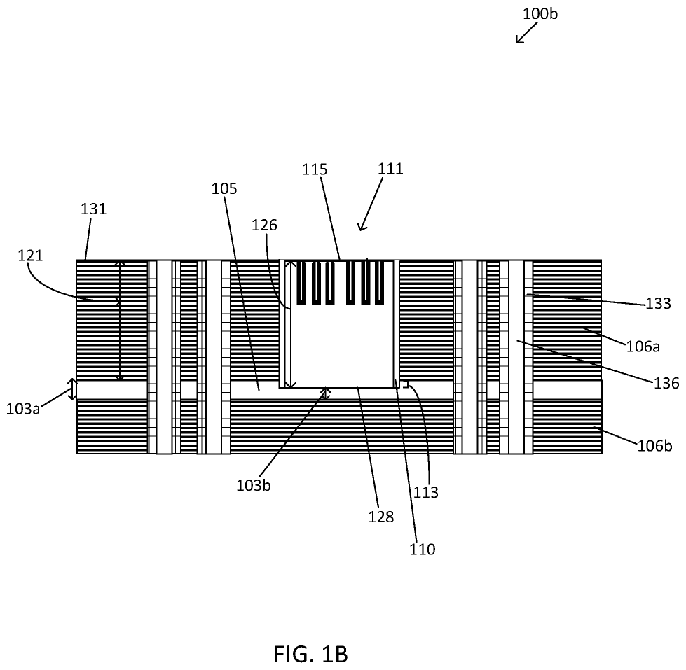

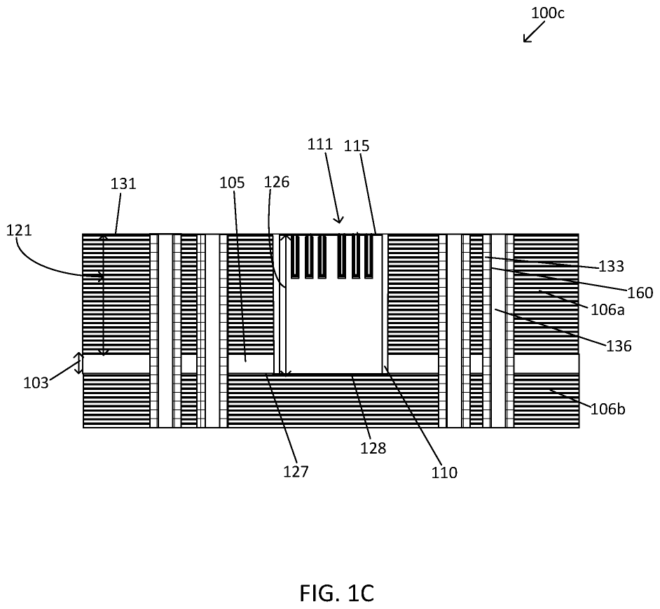

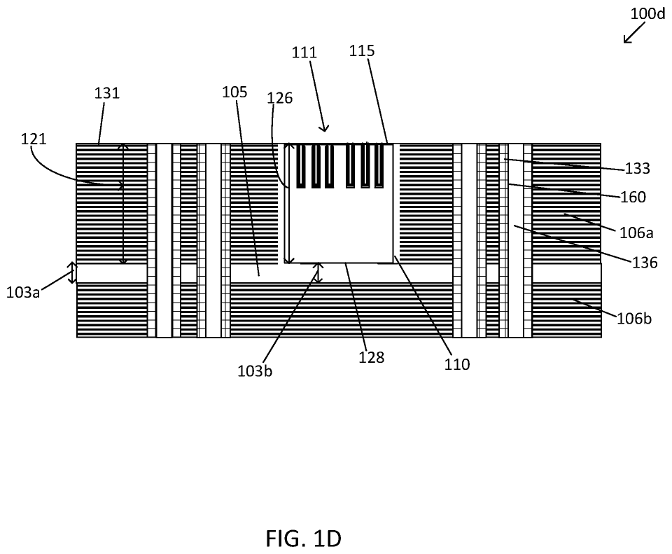

FIGS. 1A-1D illustrate embodiments of package structures including embedded passive devices, such as DTC's. The package structures are formed utilizing standard deposition and lithographic processing techniques. The methods of fabrication described herein create improved device performance in advanced 2.5D and 3D packaging.

FIG. 1A is a cross-sectional view of a portion of integrated circuit (IC) package structure 100a, in accordance with some embodiments. As shown, package substrate 102 comprises a first core layer 106a, and a second core layer 106b, wherein the core layers 106a, 106b comprise a rigid material, such as epoxy resin or fiberglass-reinforced laminate. The core layers may comprise a glass material in an embodiment. The core layers 106a, 106b provide mechanical strength and stability to the package substrate 102. In an embodiment, the core layers 106a, 106b and 106c comprise core layers of a multi-layer core structure.

Build up layers 104a, 104b may be on surfaces of the core layers 106a, 106b respectively and may comprise multiple layers of insulating materials and conductive traces 118 that are built on top of the core layers 106a, 106b using a sequential build-up process, for example. An interface layer 105 is between the core layers 106a, 106b in an embodiment. The interface layer 105 may comprise an etch stop layer 105, wherein a thickness 103 of the interface layer 105 may be optimized to position a device structure 111 within the first core layer 106a during fabrication. In an embodiment, the thickness 103 may comprise between about 50 microns to about 70 microns. In another embodiment, the thickness 103 may be between about 5 microns to about 150 microns.

In an embodiment, the interface layer 105 may comprise a copper material. In an embodiment, the interface layer 105 may comprise at least one of nickel, titanium or ruthenium or alloys thereof. In an embodiment, the interface layer 105 may comprise any suitable conductive materials and may comprise any suitable thickness 103 according to the particular application. In another embodiment, the interface layer 105 may comprise an insulator material such as silicon nitride, a silicon oxynitride or a silicon dioxide material.

The device structure 111 is embedded within the first core layer 106a, wherein the device structure 111 comprises a thickness 126. In an embodiment, the device structure 111 may comprise a silicon or a glass material but may comprise any other suitable material according to the particular application. In an embodiment the device structure 111 may comprise a solid layer of silicon rectangular in shape in plan view. One or more trenches 109 are within a portion of the device structure 111, and may be filled with a film stack 117, such as a metal/insulator/metal film stack, for example. In an embodiment, the film stack 117 may comprise a first conductive material, such as copper, on a trench 109 sidewall, a dielectric material on the first conductive material, and a second conductive material on the dielectric material.

In an embodiment, the device structure 111 including the one or more trenches 109 comprises a deep trench capacitor (DTC) 111. A top surface 115 of the DTC 111 is coplanar with a top surface 131 of the core layer 106a. The DTC 111 does not shift or rotate within the package substrate 102. In an embodiment a thickness 126 of the DTC 111 may be less than about 800 microns. In an embodiment, the thickness 126 of the DTC 111 may comprise a thickness 121 of the first core layer 106a combined with a portion 113 of a thickness 103 of the interface layer 105. The portion 113 of the thickness 103 of the interface layer 105 may be optimized to place the device structure 111 in a desired location for a particular application.

In an embodiment the portion 113 of the thickness 103 of the interface layer 105 may comprise less than about 25 percent of the thickness 103 of the interface layer 105. In another embodiment the portion 113 of the thickness 103 of the interface layer 105 may be between about 25 percent to about 50 percent of the thickness 103 of the interface layer 105. In another embodiment, the portion 113 of the thickness 103 of the interface layer 105 may be between about 50 percent to about the full thickness 103 of the interface layer 105. In an embodiment, a bottom surface 128 of the device structure 111 may be partially embedded within the interface layer 105.

An encapsulant material 110 is between the DTC 111 and the core layer 106a. The encapsulant comprises any suitable dielectric or epoxy material, such as a molding material for example. In an embodiment, a portion of the encapsulant material 110 may be between the DTC 111 and the interface layer 105. In an embodiment, the DTC 111 may be bonded to the interface layer 105 by using conventional die bond films. In an embodiment, the die bonding films may comprise a dielectric material a polymer material or an epoxy material.

In an embodiment, one or more embedded interconnect bridge structures 114a, 114b may be embedded within the build up layer 104a. The embedded interconnect bridge structures 114a, 114b may provide interconnect coupling structures between die, such as die 112a, 112b and 112c. Conductive solder balls 122 couple the die 112a, 112b and 112c to the package substrate 102. Solder balls 122 may comprise any suitable solder ball structures such as silver, gold, tin or copper materials, or combinations thereof, for example.

Conductive trace layers 118 may be distributed within the build up layers 104a, 104b. Conductive traces 118 may comprise a copper material or copper alloys, in an embodiment, but may comprise any suitable conductive material. Conductive via structures 120 and conductive traces 118 form an interconnect path with which to conductively couple any devices coupled within or to the package structure 100. A layer 116, such as a silicon nitride material or a solder material, for example, may be on a side of the package substrate opposite the die 112a, 112b and 112c.

Conductive via structures 120 extend through the first and second cores 106a, 106b as well as extending through the interface layer 105. The conductive via structures 120 couple the package substrate 102 to devices within and on the package substrate 102. The conductive via structures 120 comprise a liner material 133 and a fill material 136 within the conductive via structures 120 and are adjacent to the device structure 111. The fill material 136 may comprise a magnetic material, such as ferrous materials for example, in an embodiment. In another embodiment, the fill material 136 may comprise a dielectric material which may comprise a different material (or the same material) as the liner material 133. In another embodiment, the liner material 133 and the fill material 136 may comprise a conductive material 160 between the dielectric materials 133, 136.

FIG. 1B is a cross-sectional view of a portion of integrated circuit (IC) package structure 100b in accordance with some embodiments. As shown, a package substrate 102 comprises first and second core layers 106a, 106b, wherein an interface layer 105 is between first and second core layers 106a, 106b. A device structure 111 is embedded within the first core layer 106a, wherein a thickness 126 of the device structure 111 is slightly greater than a thickness 121 of the first core layer 106a because a portion 113 of the interface layer 105 is removed in order to optimize the placement of the device structure 111 within the first core layer 106a.

In an embodiment, the device structure 111 may comprise a silicon or organic material. Since a top surface 115 of the device structure 111 is coplanar with the top surface 131 of the first core layer 106a, the device structure 111 does not shift or rotate within the package substrate 102. A bottom surface 128 of the device structure 111 extends partially into the interface layer 105. The thickness 103a of the interface layer 105 adjacent to the device structure 111 is greater than a thickness 103b of the interface layer 105 beneath the device structure 111. An encapsulant material 110 is between the device structure 111 and the core layer 106b, wherein a portion of the encapsulant material 110 extends partially within the interface layer 105 in an embodiment. Conductive via structures 120 extend through the first and second cores 106a, 106b as well as extending through the interface layer 105 adjacent to the device structure as described in FIG. 1A. The conductive via structures 120 comprise a liner material 133 and a fill material 136 within the conductive via structures 120 wherein the fill material 136 may comprise a magnetic material in an embodiment, or may comprise a dielectric material in other embodiments. A conductive material 160 such as copper may be between the fill material 136 and the liner material 133 if both liner material 133 and fill material 136 comprise dielectric materials.

FIG. 1C is a cross-sectional view of a portion of integrated circuit (IC) package structure 100c, in accordance with some embodiments. As shown, device structure 111 is embedded within first core layer 106a, wherein a thickness 126 of the device structure 111 is greater than a thickness 121 of the first core layer 106a because the interface layer 105 is removed below the device structure 111, such that a bottom surface 128 of the device structure 111 is directly on a top surface 127 of a second core layer 106b in order to optimize the placement of the device structure 111 within the first core layer 106a. Since a top surface 115 of the device structure 111 is coplanar with the top surface 131 of the first core layer 106a, the device structure 111 does not shift or rotate within the package substrate 102.

An encapsulant material 110 is between the device structure 111 and the core layer 106b and is directly the top surface 127 of the second core layer 106b in an embodiment. Conductive via structures 120 extend through the first and second cores 106a, 106b as well as extending through the interface layer 105 adjacent to the device structure as described in FIG. 1A. The conductive via structures 120 comprise a liner material 133 and a fill material 136 within the conductive via structures 120 wherein the fill material 136 may comprise a magnetic material in an embodiment or may comprise a dielectric material in other embodiments. A conductive material 160 such as copper may be between the fill material 136 and the liner material 133 if both liner material 133 and fill material 136 comprise dielectric materials.

FIG. 1D is a cross-sectional view of a portion of integrated circuit (IC) package structure 100d, in accordance with some embodiments. As shown, an interface layer 105 is between the first and second core layers 106a, 106b. A device structure 111 is embedded within the first core layer 106a, wherein a thickness 126 of the device structure 111 is substantially the same as a thickness 121 of the first core layer 106a because a bottom surface 128 the device structure 111 is directly on a top surface of the interface layer 105 in order to optimize the placement of the device structure 111 within the first core layer 106a. A thickness 103a of the interface layer 105 adjacent to the device structure 111 is substantially the same as a thickness 103b of the interface layer 105 beneath the device structure 111. Since a top surface 115 of the device structure 111 is coplanar with the top surface 131 of the first core layer 106a, the device structure 111 does not shift or rotate within the package substrate 102.

An encapsulant material 110 is between the device structure 111 and the core layer 106b. Conductive via structures 120 extend through the first and second cores 106a, 106b as well as extending through the interface layer 105 adjacent to the device structure 111 as described in FIG. 1A. The conductive via structures 120 comprise a liner material 133 and a fill material 136 within the conductive via structures 120 wherein the fill material 136 may comprise a magnetic material in an embodiment or may comprise a dielectric material in other embodiments. A conductive material 160 such as copper may be between the fill material 136 and the liner material 133 if both liner material 133 and fill material 136 comprise dielectric materials.

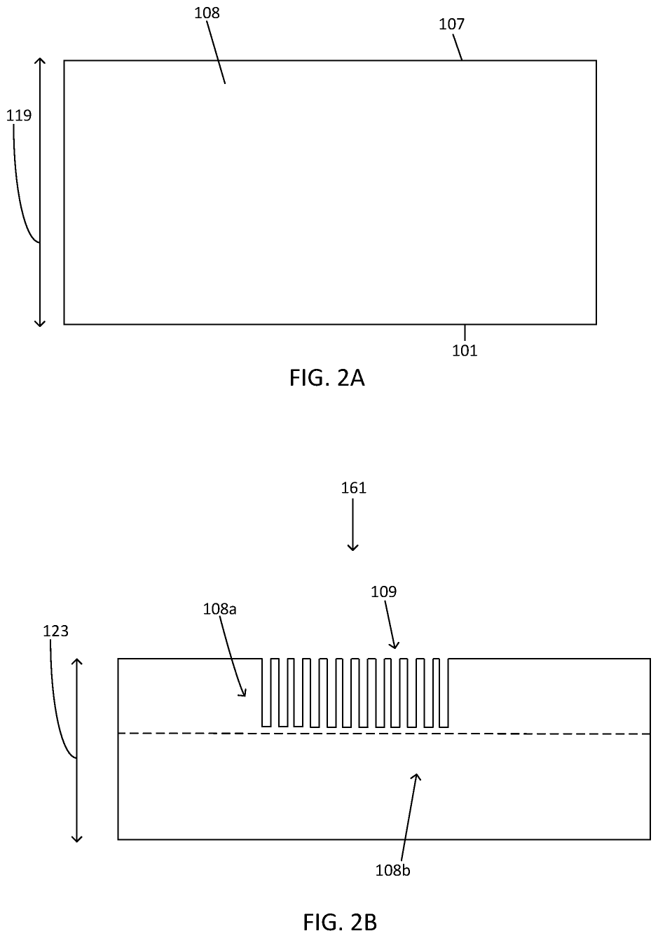

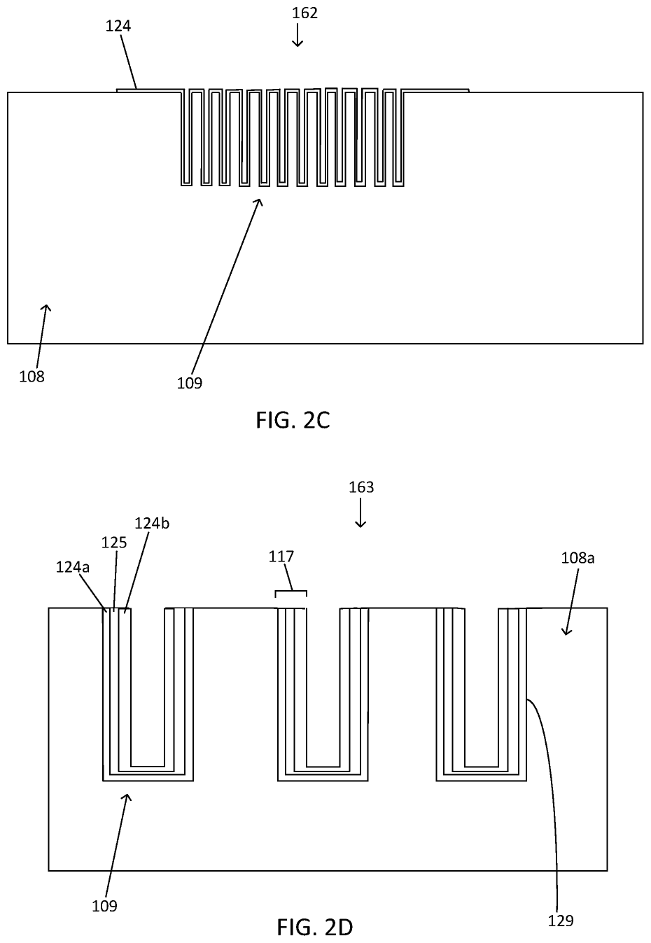

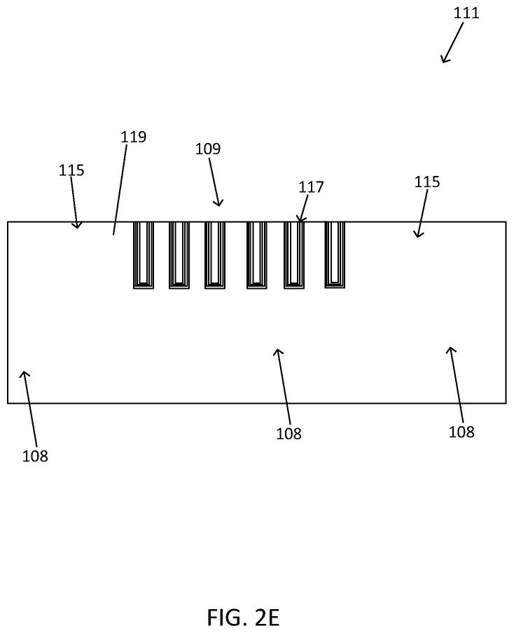

FIGS. 2A-2E illustrate embodiments of forming IC package structures (such as the IC package structures of (FIGS. 1A-1C), for example. FIG. 2A depicts a cross-sectional view of a portion of a substrate 108 according to some embodiments. As shown, the substrate 108 may comprise a device substrate 108. IC device package structures may be fabricated upon device substrate 108. Device substrate 108 may comprise a silicon material, an organic material, or any suitable material for the particular application. Device substrate 108 may comprises a thickness 119 which may be optimized according to particular design requirements, for example to limit warpage. In exemplary embodiments, the thickness 119 may comprise below about 800 microns. Device substrate 108 may comprise a first side 101 and a second side 107.

In FIG. 2B, a process 161 may be employed to form one or more trenches 109 within and through a first portion 108a of the device substrate 108. A second portion 108b is free of the one or more trenches 109 in an embodiment. Process 161 may comprise such processes as a wet or dry etch process, or a laser assisted process. In an embodiment, any process known to be suitable for forming trenches in bulk silicon may be utilized, such as a reactive ion etch process, for example, when the device substrate is silicon. In some embodiments, a laser ablation process or any other such techniques known to be suitable for forming features through a thickness of the device substrate 108 may be employed to achieve a desired diameter and feature pitch of the one or more trenches 109 within the first portion 108a of the device substrate 108.

In an embodiment, the first portion 108a of the device substrate 108 may comprise less than about 50 percent of a post etch thickness 123 of the device substrate 108. In another embodiment, the first portion 108a of the device substrate 108 may comprise less than about 35 percent of a post etch thickness 123 of the device substrate. The post etch thickness 123 of the device substrate 108 may comprise a target thickness according to the placement of the device substrate 108 within a package substrate such as within a core portion of the package substrate. For example, the post etch thickness 123 may be targeted to be substantially equal to a package core thickness or may be greater or less than a thickness of a package core thickness depending upon the particular application. In an embodiment, a pitch between individual ones of the one or more trenches 109 may comprise between about 1 micron and 10 microns but may be optimized depending upon the particular application.

In FIG. 2C, a process 162 may be employed to form a conductive material 124 within the one or more trenches 109. The process 162 may comprise any suitable process, such as a physical deposition process, such as a plasma vapor deposition (PVD) process for example, or a chemical vapor deposition (CVD) or atomic layer deposition (ALD) process, followed by a patterning process. The conductive material 124 may comprise a copper material 124 or copper alloys, in an embodiment, but may comprise any suitable conductive material. In an embodiment, the conductive material 124 may comprise a polysilicon material or any other low resistivity metal for Vss and Vdd electrodes, while iridium/IrO2 or ruthenium/RuO2, may be used for contact metals.

The conductive material 124 forms an interconnect path with which to conductively couple to any devices within or on a package structure. The conductive material 124 may comprise a portion of a passive device formed within the device substrate 108, such as a deep trench capacitor or an inductor, for example.

FIG. 2D depicts a section of the first portion 108a of the device substrate 108 wherein a film stack 117 comprising a metal/insulator/metal (MIM) film stack may be formed using formation process 163 within the one or more trenches 109. In an embodiment, the process 163 may comprise such processes as chemical vapor deposition (CVD) or physical vapor deposition (PVD), for example. In an embodiment, a first conductive material 124a may be formed on a sidewall 129 of the one or more trenches 109 wherein the sidewall 129 may comprise a sidewall of the device substrate 108.

In an embodiment, the first conductive material 124a may comprise copper or a copper alloy but may comprise any suitable conductive material. In an embodiment, a dielectric material 125 may be formed on the conductive material. The dielectric material 125 may comprise a silicon oxide or a silicon nitride material, in an embodiment, but may comprise any suitable dielectric material. In an embodiment, the dielectric material 125 may comprise titanium dioxide, hafnium dioxide, a parylene conformal coating, or combinations thereof. A second conductive material 124b may be formed on the dielectric material 125, wherein the second conductive material 124b may comprise the same or a different conductive material as the first conductive material 124a. In an embodiment, any suitable combinations of film layers/materials may be formed within the one or more trench openings utilizing process 163, such as an inductor film stack.

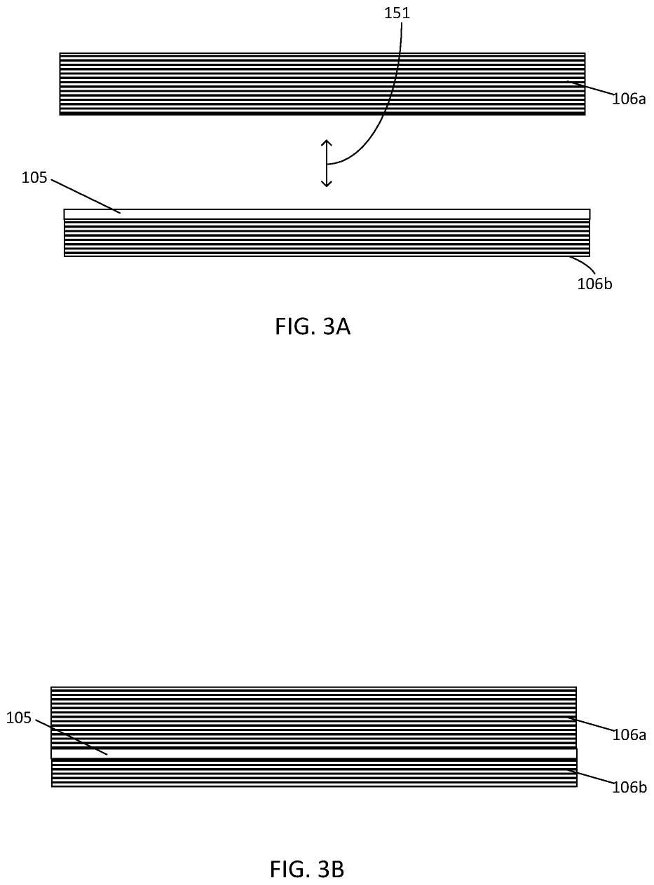

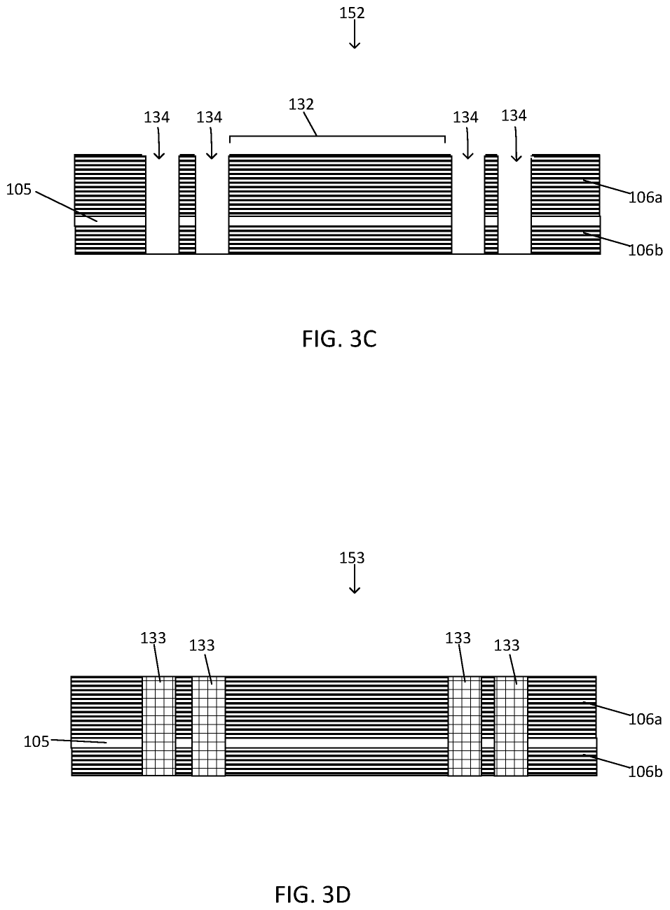

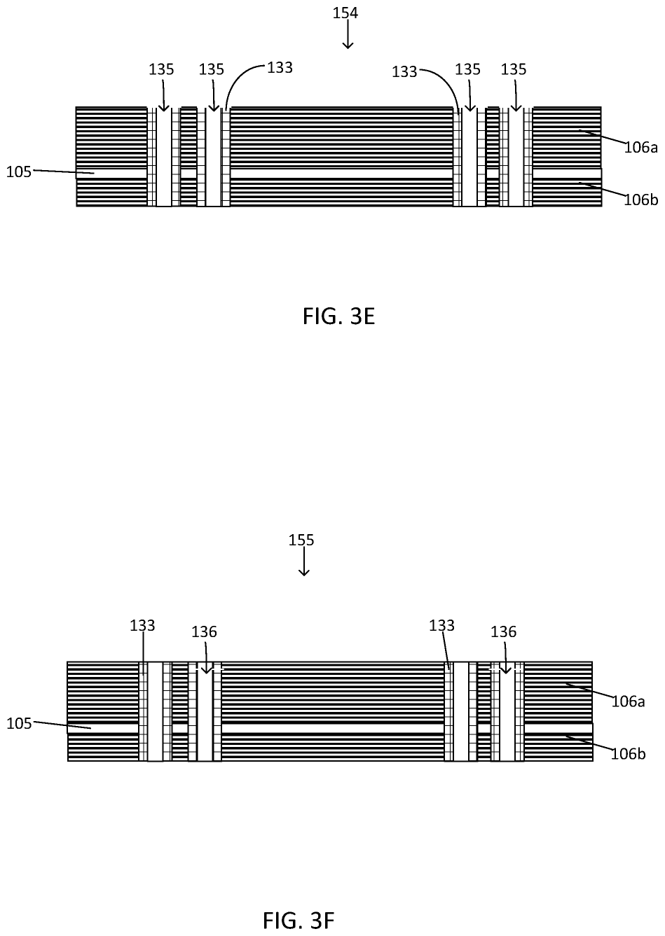

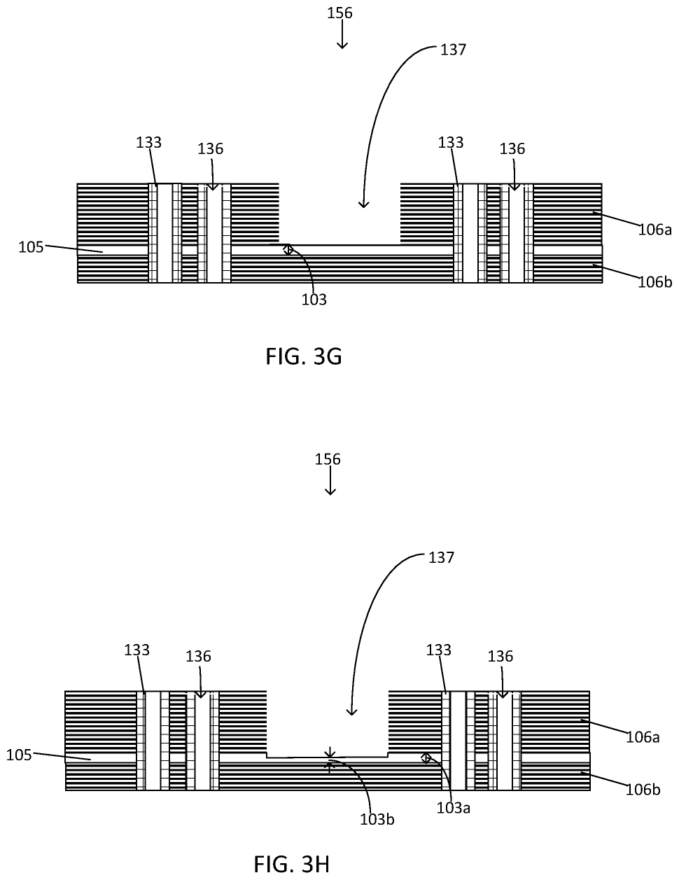

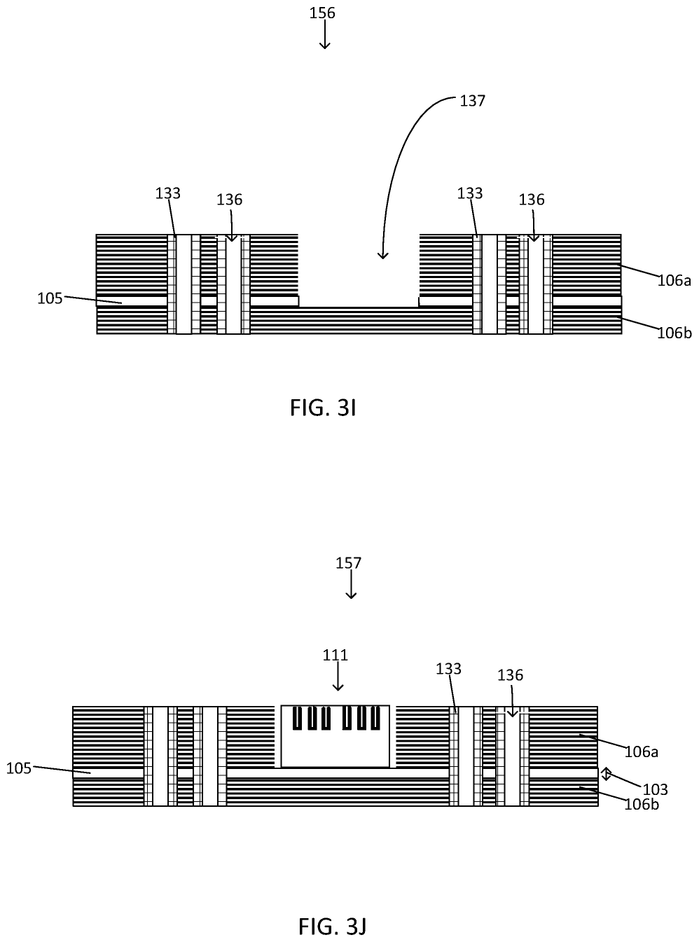

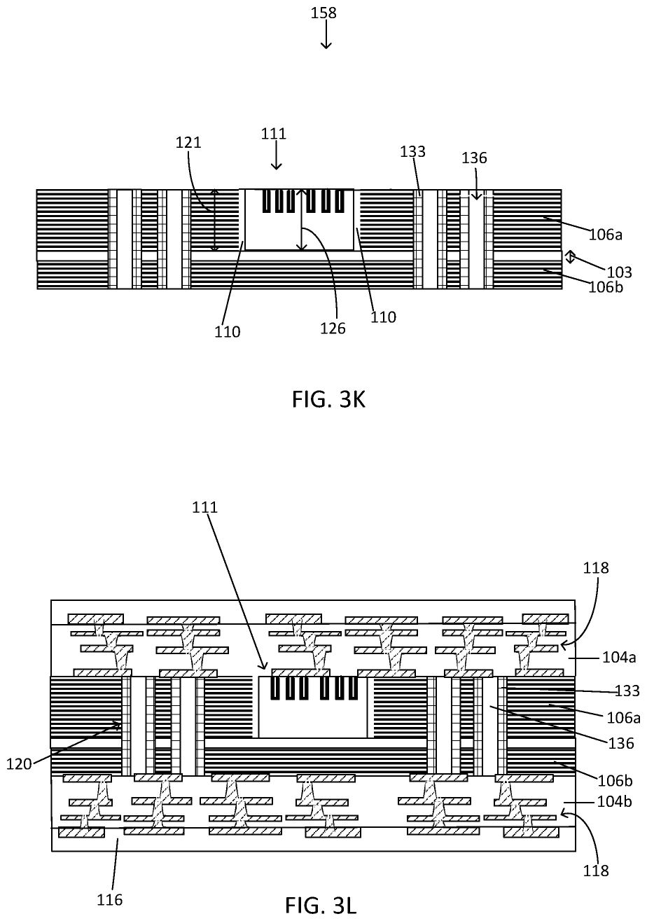

FIG. 2E depicts a deep trench capacitor (DTC) structure 111 comprising one or more trenches 109 within the device substrate 108. The one or more trenches 109 comprise a film stack 117 comprising a metal/insulator/metal (MIM) film stack which are to be conductively coupled to conductive traces/via structures within a package structure such as any of the package structures of FIGS. 1A-1D, for example. FIGS. 3A-3L depict a method of placing a passive device, such as a DTC, within a first core of a core stack.

FIG. 3A depicts a portion of a two-layer package core 106a, 106b, wherein an interface layer 105 is on the second package core 106b in an embodiment. The first and second core layers 106a, 106b may comprise an FR-4 (Flame Retardant) mix of elements, including titanium epoxy laminates and traces of copper. In an embodiment, the first and second core layers 106a, 106b may comprise an epoxy material or a glass material. The first and second core layers 106a, 106b may comprise a rigid surface coated on either side with the interface layer 105 material, in an embodiment. In an embodiment, at least one of the core layers 106a, 106b may comprise a polymer material with the interface material on the polymer material. Although two core layers are shown, any number of core layers 106 may be stacked on each other depending upon the particular application.

The interface layer 105 may comprise a conductive material such as copper, a polymer material or a silicon nitride or silicon oxy nitride material when the first and second core layers 106a, 106b comprise a glass material. In another embodiment, the interface material 105 may comprise dielectric materials such as silicon oxide, silicon nitride, a polytetrafluoroethylene (PTFE) polymer or silicon oxynitride but may comprise any suitable dielectric material. The interface layer 105 may comprise an etch stop layer in an embodiment, wherein a thickness of the interface layer 105 may be used to optimize the location of a device structure to be placed within the first core layer 106a.

A process 151 may be utilized to bond the first core layer 106a to the second core layer 106b, with the interface layer 105 in between. In an embodiment, the bonding process 151 may comprise a hybrid bond process but may comprise any suitable bonding process according to the particular application. FIG. 3B depicts the first and second core layers 106a, 106b subsequent to the application of the process 151. FIG. 3C depicts a process 152 which forms one or more openings 134 adjacent to a central portion 132 of the first core layer 106a. The process 152 may include any suitable etching and/or drilling process to remove portions of the first core layer 106a, the interface layer 105 and the second core layer 106b to form one or more openings 134. In an embodiment, when the first and second core layers 106a, 106b comprise a glass material, a laser assisted deep etching process may be utilized. In another embodiment, when the first and second core layers 106a, 106b comprise an epoxy material, a laser ablation process may be utilized.

The one or more openings 134 may be filled with a liner material 133 (FIG. 3D) utilizing formation process 153. The liner material 133 may comprise an epoxy material, in an embodiment or any other suitable dielectric material. In another embodiment, the liner material 133 may comprise a conductive material. The liner material 133 may be in contact with a portion of the interface layer 105, wherein the liner material 133 extends through the first and second core layers 106a, 106b as well as through the interface layer 105. In FIG. 3E, a liner opening 135 may be formed within the liner material 133 utilizing a liner opening process 154. The liner opening process 154 may comprise a drilling process in an embodiment or may comprise any suitable removal/etching process.

In FIG. 3F, a formation process 155 may be utilized to form a fill material 136 within the liner opening 135, which may comprise a magnetic material in an embodiment. In other embodiments, the fill material 136 may comprise a conductive material, such as copper for example. In another embodiment, the formation of the fill material 136 may be optional and the liner opening 135 may be completely filled with a conductive material, such as copper for example. In another embodiment, the fill material 136 may comprise a dielectric material comprising a conductive material between the liner material 133 and the fill material 136.

FIGS. 3G-3I depict the formation of a cavity 137 within a portion of the first core layer 106a utilizing a cavity formation process 156. The formation process 156 may comprise a glass removal process or an epoxy removal process, depending upon the requirements for the type of core layer 106a, 106b materials. The cavity formation process 156 may be optimized to remove a portion of the first core layer 106a such that the cavity 137 may receive a device structure, such as device structure 111 depicted in FIG. 1A, for example.

The cavity formation process 156 may stop on a surface of the interface layer 105 in an embodiment as shown in FIG. 3G, wherein the interface layer 105 comprises substantially the same thickness 103 between the first and second core layers 106a, 106b. As depicted in FIG. 3H, a partial amount of the interface layer 105 may be removed, wherein a thickness 103b of the interface layer 105 beneath the cavity 137 is less than a thickness 103a of the interface layer 105 adjacent to the cavity 137. FIG. 3I depicts an embodiment wherein the cavity formation process 156 removes substantially all of the interface layer 105 beneath the cavity 137. The amount or the interface layer 105 to be removed depends upon the particular design requirements.

A device structure 111 may be placed within the cavity 137 (FIG. 3J) utilizing a placement process 157 such as a pick and place process for example. The placement of the device structure 111 may be tuned by optimizing a thickness 103 of the interface layer 105 during the cavity formation process 156 in order to prevent the device structure 111 from shifting or rotating within the first core layer 106a. Thus the embodiments of the present disclosure enable the use of thicker device structures 111, such as device structures comprising greater than about 600 microns in thickness. The embodiments herein can be utilized whenever a target thickness of the first core layer 106a is greater than a thickness of the DTC 111. In an embodiment, the DTC 111 may comprise a thickness of 1000 microns and the first core layer 106a may comprise a thickness of 1500 microns for example.

FIG. 3K depicts the formation of an encapsulant material 110 on side surfaces of the device structure 111 utilizing an encapsulant formation process 158. The encapsulant material 110 may be formed within the space between the first core layer 106a and the device structure 111. The encapsulant material 110 may comprise materials such as a mold material, a build up material, or a photo imageable dielectric material, for example.

The device structure 111 may comprise a passive device structure such as a DTC 111 according to embodiments herein. In an embodiment, a thickness 121 of the first core layer 106a is substantially the same as a thickness 126 of the device structure 111, such that the device structure 111 and the core layer 106a are substantially coplanar with each other. In other embodiments, a thickness 126 of the device structure 111 may be greater than a thickness of the first core layer 106a due to the optimization/removal of a portion of the interface layer 105.

In FIG. 3L, build up materials 104a, 104b including conductive traces 118 may be formed on the first and second core layers 106a, 106b respectively, wherein the device structure 111 is conductively coupled to the conductive traces 118 by conductive via structure 120. In an embodiment, multiple cores may be stacked together according to particular design requirements. A layer 116, such as a silicon nitride material or a solder material, for example, may be formed on the build up layer 104b and may serve as a passivation layer, for example.

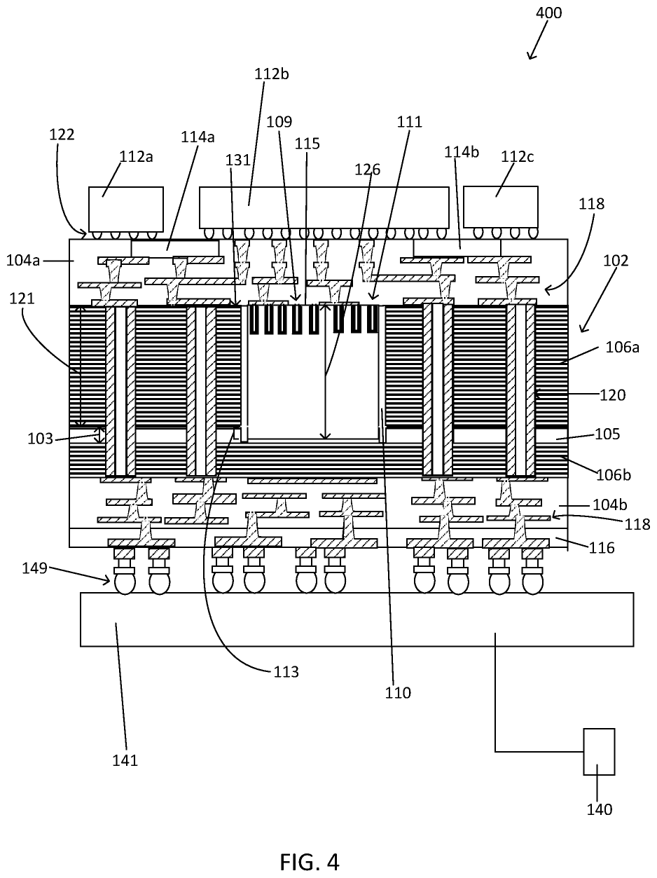

FIG. 4 depicts an IC multi core package structure 400, wherein dies 112a, 112b and 112c are on a package substrate 102, such as a package substrate 102 of FIG. 1A, for example. In some embodiments, the dies 112a, 112b and 112c may comprise chiplet structures 112a, 112b and 112c which may comprise components of a system on a chip (SOC) structure. The dies 112a, 112b and 112c are coupled to each other and to a device structure 111 such as a DTC 111, according to any of the embodiments disclosed herein, through a redistribution layer (RDL) metallization 118. The device structure 111 is embedded in a first core layer 106a, wherein a top surface 115 of the device structure 111 and a top surface 131 of the first core layer 106a are substantially coplanar with each other. A thickness 126 of the device structure 111 may comprise a thickness 121 of the first core 106a plus a portion 113 of the thickness 103 of the interface layer 105.

Any number of die/devices may be coupled to the package substrate 102. The package substrate 102 may be coupled to a board 141, such as a printed circuit board, in an embodiment. Conductive bumps 122 may comprise any conductive element for coupling to an outside die or other device. In an embodiment, the conductive bumps 122 may include silver, tin, or copper, or combinations or alloys thereof. In an embodiment, one or more embedded interconnect bridge structures 114a, 114b may be embedded within the build up layer 104a. The embedded interconnect bridge structures 114a, 114b may provide interconnect coupling structures between die, such as die 112a, 112b and 112c. Conductive vias 120, such as those depicted in FIGS. 1A-1D, for example extend through the first core layer 106a and a second core layer 106b and extend through interface layer 105 to couple with the board 141. The board 141 may be coupled to the package substrate 102 through solder structures 149. A power supply 140, which may comprise any suitable power supply as known in the art, may be coupled to dies 112a, 112b and 112c via IC package substrate 102, in an embodiment.

Discussion now turns to operations for assembling and/or fabricating the discussed structures.

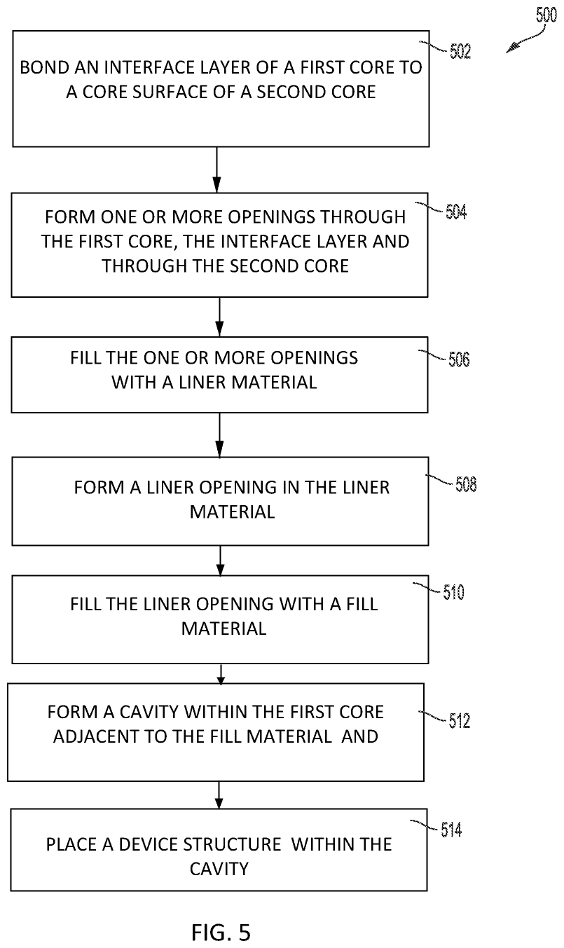

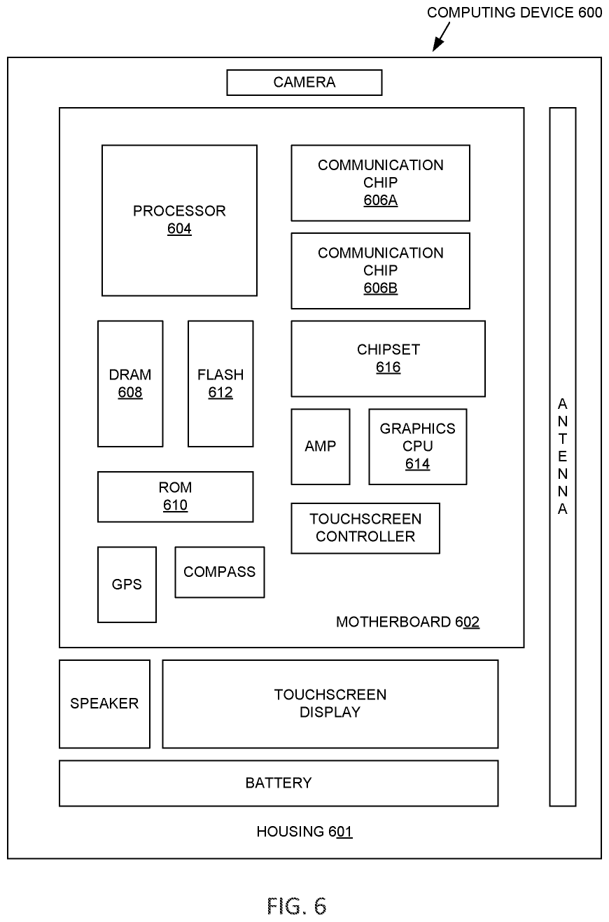

FIG. 5 is a flow chart of a process 500 of fabricating package structures according to some embodiments. For example, process 500 may be used to fabricate any of the microelectronic IC package structures of FIGS. 3A-3L.

As set forth in block 502, an interface layer of a first core may be bonded to a core surface of a second core. In an embodiment, the first and second cores may comprise first and second core layers and may comprise a rigid material, such as epoxy resin or fiberglass-reinforced laminate. The first and second cores provide mechanical strength and stability to the package substrate. The interface layer may comprise a copper layer or a dielectric layer in some embodiments, as described above. The interface layer may serve to bond the first core to the second core. In an embodiment, the interface layer may comprise a thickness of between about 5 microns to about 150 microns.

At block 504, one or more openings may be formed through the first core, the interface layer and through the second core. In an embodiment, the one or more openings are formed adjacent to a central portion of the first core. The openings may be formed by utilizing a laser drill process or an etching process, in an embodiment.

At block 506, the one or more openings may be filled with a liner material, such as a dielectric material. The liner material may comprise such dielectric materials as an epoxy material or a build up material for example. In another embodiment, the one or more openings may be completely filled with a conductive material such as copper or copper alloys. At block 508, a liner opening may be formed in the liner material. The liner openings may be formed using an etch or laser drill process, for example.

At block 510, the liner openings may be filled with a fill material. In an embodiment, the fill material may comprise a magnetic material. In other embodiments, the fill material may comprise a dielectric material, where a conductive material may be formed between the liner material and the fill material within the liner opening. In an embodiment, the liner and fill material may be the same dielectric material, or they may be different dielectric materials.

At block 512, a cavity may be formed within the first core adjacent to the fill material. The cavity may be formed utilizing any suitable process to remove a portion of the first core. The cavity may be formed such that the cavity formation process stops on the interface layer, removes a portion of the interface layer or removes all of the interface layer within the cavity. The amount of the interface layer to be removed beneath the cavity is optimized for a thickness of a device structure that may be subsequently placed within the cavity in order to eliminate shifting and/or rotation of the device structure subsequent to placement within the cavity.

At block 514 a device structure may be placed within the cavity. In an embodiment, the device structure may comprise a silicon material. In an embodiment, the device structure may comprise any suitable material such as glass. In an embodiment, the device structure has a thickness that may vary with implementation, for example to limit warpage. In an embodiment a thickness of the device structure is advantageously below about 800 microns, but may be any suitable thickness according to the particular application.

The device structure may comprise one or more trenches, each trench comprising a MIM layer on sidewalls of the trenches. The device structure may comprise a trench capacitor structure with electrical contacts to electrically couple to a package substrate. In other embodiments, passive device structures such as a DTC or an inductor may be formed within the one or more trenches depending upon the particular application requirements. Subsequent to the device structure placement and encapsulation of sidewalls of the device structure, build up layers may be formed on the first and second cores, such as are depicted in FIG. 3L for example, for example. Top surfaces of the first core and top surfaces of the device structure are coplanar with each other.

FIG. 6 illustrates an electronic or computing device 600 in accordance with one or more implementations of the present description. The computing device 600 may include a housing 601 having a board 602 disposed therein. The computing device 600 may include a number of integrated circuit components, including but not limited to a processor 604, at least one communication chip 606A, 606B, volatile memory 608 (e.g., DRAM), non-volatile memory 610 (e.g., ROM), flash memory 612, a graphics processor or CPU 614, a digital signal processor (not shown), a crypto processor (not shown), a chipset 616, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 602. In some implementations, at least one of the integrated circuit components may be a part of the processor 604.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include an apparatus having a first core layer, an interface layer on the first core layer, and a second core layer the interface layer. A device structure is on the interface layer and embedded within the first core layer. The device structure comprising one or more trench capacitors extending partially through a thickness of the device structure. One or more conductive via structures are adjacent to the device structure, wherein the one or more conductive via structures extend through the interface layer.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-6. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments is an apparatus comprising a first core layer, an interface layer on the first core layer, a second core layer on the interface layer, and a device structure on the interface layer. The device structure comprising one or more trench capacitors extending partially through a thickness of the device structure, and one or more conductive via structures adjacent to the device structure, wherein the one or more conductive via structures extend through a portion of the interface layer.

In second examples the first example further comprises wherein the one or more conductive via structures extend through the first core layer and the second core layer.

In third examples wherein any of claims 1-2 further comprise wherein the interface layer comprises one of a copper material or a dielectric material and comprises a thickness of between about 50 microns to about 70 microns.

In fourth examples wherein any of claims 1-3 further comprise wherein a first build up layer is on the first core layer and a second build up layer is in the second core layer.

In fifth examples wherein any of claims 1-4 further comprise wherein a first build up layer is on the first core layer and a second build up layer is in the second core layer.

In sixth examples wherein any of claims 1-5 further comprise wherein the device structure is embedded within the first core layer, wherein a thickness of the device structure is substantially the same as a thickness of the first core layer, and wherein a device substrate portion of the device structure comprises one of silicon or glass.

In seventh examples wherein any of claims 1-6 further comprise wherein a portion of the interface layer below a surface of the device structure comprises a first thickness and a portion of the interface layer adjacent to the device structure comprises a second thickness, wherein the second thickness is greater than the first thickness.

In eighth examples wherein any of claims 1-7 further comprise wherein the device structure comprises a thickness greater than about 600 microns.

In ninth examples wherein any of claims 1-8 further comprise wherein a mold material is between a sidewall of the device structure and a sidewall of the first core layer.

In tenth examples wherein any of claims 1-9 further comprise wherein the mold material comprises one or more of a build up material, an epoxy mold materials or a photo imageable dielectric (PID) material.

In eleventh examples wherein any of claims 1-10 further comprise wherein individual ones of the one or more conductive via structures comprise a liner dielectric material on a sidewall of the individual ones of the conductive via structures and a fill material on the liner dielectric material.

In twelfth examples wherein any of claims 1-10 further comprise a die coupled to the device structure.

A thirteenth example is an apparatus comprising: a first core layer on an interface layer; a second core layer on the interface layer, opposite the first core layer; a device structure within the first core layer, the device structure comprising: one or more trench capacitors extending partially through a thickness of the device structure. One or more conductive via structures adjacent to the device structure, wherein the one or more conductive via structures extend through the first and second core layers and through a portion of the interface layer.

In fourteenth examples wherein example 13 further comprises wherein individual ones of the one or more conductive via structures comprise a first dielectric material on a sidewall of the individual ones of the one or more conductive via structures and a second dielectric material on the first dielectric material.

In fifteenth examples wherein any of claims 13-14 further comprise wherein the one or more conductive via structures are substantially filled with a copper material, and the device structure comprises a glass substrate, and further comprising a die coupled to the device structure.

In sixteenth examples wherein any of claims 13-15 further comprise wherein individual ones of the one or more conductive via structures comprise a dielectric material on a sidewall of the individual ones of the one or more conductive via structures, and wherein a magnetic material is on the dielectric material.

In seventeenth examples wherein any of claims 13-15 further comprise wherein the device structure is directly on the second core layer, and wherein a bottom surface of the device structure is free of the interface layer.

An eighteenth example is a method comprising: bonding an interface layer of a first core to a core surface of a second core; forming one or more openings through the first core, the interface layer and through the second core; filling the one or more openings with a liner material; forming a liner opening in the liner material; filling the liner opening with a fill material; forming a cavity within the first core layer adjacent to fill material; and placing a device structure within the cavity.

In nineteenth examples wherein example 18 further comprises wherein the device structure comprises a trench capacitor structure.

In twentieth examples wherein any of examples 18-19 further comprise wherein forming the cavity comprises removing a portion of the interface layer.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a first core layer;
an interface layer on the first core layer;
a second core layer on the interface layer;
a device structure on the interface layer, the device structure comprising:
one or more trench capacitors extending partially through a thickness of the device structure; and
one or more conductive via structures adjacent to the device structure, wherein the one or more conductive via structures extend through a portion of the interface layer.

2. The apparatus of claim 1, wherein the one or more conductive via structures extend through the first core layer and the second core layer.

3. The apparatus of claim 1, wherein the interface layer comprises one of a copper material or a dielectric material and comprises a thickness of between about 50 microns to about 70 microns.

4. The apparatus of claim 1, wherein a first build up layer is on the first core layer and a second build up layer is in the second core layer.

5. The apparatus of claim 1, wherein individual ones of the one or more trench capacitors comprise:
a first trench interface layer on a device structure sidewall;
a trench dielectric layer on the first trench interface layer; and
a second trench interface layer on the trench dielectric layer.

6. The apparatus of claim 1, wherein the device structure is embedded within the first core layer, wherein a thickness of the device structure is substantially the same as a thickness of the first core layer, and wherein a device substrate portion of the device structure comprises one of silicon or glass.

7. The apparatus of claim 1, wherein a portion of the interface layer below a surface of the device structure comprises a first thickness and a portion of the interface layer adjacent to the device structure comprises a second thickness, wherein the second thickness is greater than the first thickness.

8. The apparatus of claim 1, wherein the device structure comprises a thickness greater than about 600 microns.

9. The apparatus of claim 1, wherein a mold material is between a sidewall of the device structure and a sidewall of the first core layer.

10. The apparatus of claim 9, wherein the mold material comprises one or more of a build up material, an epoxy mold material or a photo imageable dielectric (PID) material.

11. The apparatus of claim 1, wherein individual ones of the one or more conductive via structures comprise a liner dielectric material on a sidewall of the individual ones of the conductive via structures and a fill material on the liner dielectric material.

12. The apparatus of claim 1, further comprising a die coupled to the device structure.

13. An apparatus, comprising:
a first core layer on an interface layer;
a second core layer on the interface layer, opposite the first core layer;
a device structure within the first core layer, the device structure comprising:
one or more trench capacitors extending partially through a thickness of the device structure; and
one or more conductive via structures adjacent to the device structure, wherein the one or more conductive via structures extend through the first and second core layers and through a portion of the interface layer.

14. The apparatus of claim 13, wherein individual ones of the one or more conductive via structures comprise a first dielectric material on a sidewall of the individual ones of the one or more conductive via structures and a second dielectric material on the first dielectric material.

15. The apparatus of claim 13, wherein the one or more conductive via structures are substantially filled with a copper material, and the device structure comprises a glass substrate, and further comprising a die coupled to the device structure.

16. The apparatus of claim 13, wherein individual ones of the one or more conductive via structures comprise a dielectric material on a sidewall of the individual ones of the one or more conductive via structures, and wherein a magnetic material is on the dielectric material.

17. The apparatus of claim 16, wherein the device structure is directly on the second core layer, and wherein a bottom surface of the device structure is free of the interface layer.

18. A method, comprising:
bonding an interface layer of a first core to a core surface of a second core;
forming one or more openings through the first core, the interface layer and through the second core;
filling the one or more openings with a liner material;
forming a liner opening in the liner material;
filling the liner opening with a fill material;
forming a cavity within the first core adjacent to fill material; and
placing a device structure within the cavity.

19. The method of claim 18, wherein the device structure comprises a trench capacitor structure.

20. The method of claim 18, wherein forming the cavity comprises removing a portion of the interface layer.
